(19) United States
(12) Patent Application Publication
(10) Pub. No.: US 2024/0431093 A1
(43) Pub. Date: Dec. 26, 2024

(54) DUAL FIELD EFFECT TRANSISTOR 4F2 CELL

(71) Applicant: Applied Materials, Inc., Santa Clara, CA (US)

(72) Inventor: Fredrick Fishburn, Aptos, CA (US)

(73) Assignee: Applied Materials, Inc., Santa Clara, CA (US)

(21) Appl. No.: 18/732,896

(22) Filed: Jun. 4, 2024

Related U.S. Application Data
(60) Provisional application No. 63/509,209, filed on Jun. 20, 2023.

(51) Int. Cl. H10B 12/00

(52) U.S. Cl. CPC H10B 12/20; H10B 12/05; H10B 12/482; H10B 12/488

(57) ABSTRACT

The present technology is generally directed to vertical dynamic random-access memory (DRAM) cells and arrays, and methods of forming such cells and arrays, that contain a shared word line between two adjacent channels. Cells include a bit line arranged in a first horizontal direction, a first channel, a second channel, and a shared word line arranged in a second horizontal direction between the first channel and the second channel. Cells include where the first channel and the second channel extend in a vertical direction that is orthogonal to the first horizontal direction and the second horizontal direction, such that the bit line intersects with a source/drain region of the first channel and the second channel, and the shared word line intersects with a gate region of both the first channel and the second channel.

### CROSS-REFERENCE TO RELATED APPLICATION

This application claims the benefit of U.S. Provisional No. 63/509,209 filed on Jun. 20, 2023, entitled “DUAL FIELD EFFECT TRANSISTOR 4F2 CELL,” the entire contents of which are incorporated herein by reference.

### TECHNICAL FIELD

This disclosure generally describes designs for a 4F2 two-dimensional dynamic random access memory array. More specifically, this disclosure describes a 4F2 memory array with decreased floating body effect.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. The manufacturing of a DRAM cell includes the fabrication of a transistor, a capacitor, and three contacts: one each to the bit line, the word line, and the reference voltage. There is a continuous desired to decrease the size of individual cells and to increase memory cell density to allow more memory to be included on a single memory chip, especially for densities greater than 256 Megabits. However, further increases in density have proven problematic. Therefore, improvements in the art are needed.

### BRIEF SUMMARY

Embodiments of the present technology are generally directed to vertical dynamic random-access memory (DRAM) cells that contains a shared word line between two adjacent channels. Cells include a bit line arranged in a first horizontal direction, a first channel, a second channel, and a shared word line arranged in a second horizontal direction between the first channel and the second channel. Cells include where the first channel and the second channel extend in a vertical direction that is generally orthogonal to the first horizontal direction and the second horizontal direction, such that the bit line intersects with a source/drain region of the first channel and the second channel, and the shared word line intersects with a gate region of both the first channel and the second channel.

In embodiments, cells include where the vertical dynamic random access memory cell contains only one word line for every two channels. In more embodiments, a first dielectric layer extends from a first end of a word line trench to a second end of the word line trench along a first side, where the second end is opposite the first end, and a second dielectric layer extends from the first end of the word line trench to the second end of the word line trench along a second side, where the second side is opposite the first side. In further embodiments, the first dielectric layer is formed from a material having a first work function, and the second dielectric layer is formed from a material having a second work function, where the first work function is different than the second work function.

In embodiments, a first side of the word line trench is adjacent to the first channel and the second side is adjacent to the second channel. In additional embodiments, the first channel is a n-MOS channel and the second channel is a p-MOS channel. Additionally or alternatively, in embodiments, the first dielectric material includes a positive work function material. In embodiments, the first dielectric layer material comprises an oxide containing aluminum (Al), niobium (Nb), Tantalum (Ta), a metallic substance having Fermi level lower than that of hafnium (Hf), or combinations thereof. In yet more embodiments, the second dielectric layer material includes a negative work function material. In further embodiments, the second dielectric layer material includes an oxide containing one or more lanthanum species or a combination of species.

The present technology is also generally directed to vertical cell dynamic random-access memory (DRAM) arrays having a reduced size and increased memory density. Arrays include a first vertical dynamic random access memory cell disposed adjacent to a second vertical dynamic random access memory cell. Each cell contains a bit line arranged in a first horizontal direction, a first channel, a second channel, and a word line arranged in a second horizontal direction between the first channel and the second channel. Cells include where the first channel and the second channel extend in a vertical direction that is generally orthogonal to the first horizontal direction and the second horizontal direction, such that the bit line intersects with a source/drain region of the first channel and the second channel, and the word line intersects with a gate region of both the first channel and the second channel. Arrays also include an electrical isolation between the first vertical dynamic access memory cell and the second vertical dynamic random access memory cell.

In embodiments, the first vertical dynamic random access memory cell and the second vertical dynamic random access memory cell each include only one word line for every two channels. In more embodiments, arrays include a third vertical dynamic random access memory cell adjacent to the second vertical dynamic random access memory cell, where an electrical isolation is disposed between the second vertical dynamic random access memory cell and the third vertical dynamic random access memory cell, and the third vertical dynamic random access memory cell includes a shared word line between two adjacent channels. In further embodiments, an electrical isolation includes one or more dielectric materials, an air gap, or a combination thereof. In more embodiments, arrays include a substrate layer disposed between the bit line and the source/drain region of the first channel and the second channel.

The present technology is also generally directed to methods for forming vertical dynamic random-access memory (DRAM) cells and arrays. Methods include etching a word line trench between a first vertically extending channel and a second vertically extending channel, where the word line trench has a first end opposite a second end and a first side opposite a second side. Methods include forming a shared word line in the word line trench such that the word line intersects with a gate region of both the first vertically extending channel and the second vertically extending channel.

In embodiments, methods include lining the word line trench with a gate dielectric prior to forming the shared word line. In further embodiments, methods include forming a first dielectric material over the gate dielectric along the first side of the word line trench and forming a second dielectric material over the gate dielectric along the second side of the word line trench. In further embodiments, methods include forming a substrate by sidewall epitaxy over the vertical dynamic random access memory cell adjacent to the second end of the word line trench and a bit line layer of the substrate layer. In yet more embodiments, methods include where the substrate layer is formed from alternating layers of a p-type substrate material, a selective etch material, and a n-type substrate material. Additionally or alternatively, in embodiments, methods include removing the selecting etch material, and forming source/drain connections between the first vertically extending channel and the bit line and the second vertically extending channel and the bit line.

Such technology may provide numerous benefits over conventional systems and techniques. For example, the processes and devices may reduce the number of word lines necessary, allowing increased memory density and decreased word line pitch. Namely, the processes and devices may significantly increase memory density while maintaining excellent electrical response and properties, as such increase in density may be exhibited in conjunction with increased word line width. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 1D illustrates a cross-sectional view of a conventional 4F² memory array.

FIG. 2 shows selected operations in a formation method according to embodiments of the present technology.

FIG. 3 illustrates a schematic view of a 4F² memory array according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

DRAM arrays classified as 4F² are important as they require fewer patterned layers due to the memory cell being a cross point cell. However, as the minimum or critical feature size (referred to as “F”) continues to shrink, it is becoming increasing difficult to increase memory density in existing 4F² memory arrays. For instance, existing 4F² memory cells are generally double gated, meaning that each channel is flanked by two dedicated word lines in order to carefully control each channel electrostatically. Such an arrangement prevents neighboring channels from coupling, as well as unintended channel activation. Thus, due to such advantages in double gated arrangements, efforts to maintain the word line orientation, such as shrinking word line thickness (or width) have been attempted.

However, each word line has a minimum thickness due to pitch and maximum resistance requirements. Namely, efforts to shrink pitch by decreasing word line widths or thicknesses have resulted in unfavorable increases in resistance in the word line. Therefore, efforts to decrease word line thickness have proven insufficient to substantially increase the memory density of 4F² memory arrays.

Attempts have been made to remove the gates between adjacent channels, in order to provide a single gated memory cell. In such endeavors, two gates disposed between adjacent channels may be replaced with an insulative material, such as an air gap. However, even with advances in materials providing increased insulation with reduced thicknesses or widths, such single gated efforts have still failed to substantially decrease 4F² memory cell size, such as a size decrease of at least 5%.

In addition, 4F² memory cells have a transistor channel disposed between the bit line and the capacitor layers, and thus no common substrate connecting the channels, resulting in a floating body effect for these transistors. Conventional 4F² DRAM devices exhibit off-leakage current issues stemming from the floating body effect, such as hole accumulation in the body of a 4F² DRAM device due to the isolated channels. For instance, electron-hole pairs will form in a semiconductor channels due to band-to-band tunneling. While the electrons can flow into the n-type source or drain regions of the transistor, the holes cannot. For 4F² DRAM devices without a substrate connection, the holes have no path to leave the channel and will continue to accumulate. Thus, the floating body effect may lead to channel activation without gate activation, which eventually translates into leakage current from the capacitor, or data storage side of the device.

The present technology overcomes these and other problems by forming two adjacent transistors (such as a field effect transistor, FET) in a vertical cell dynamic random-access memory (DRAM) array with a shared word line. Such an arrangement allows for the formation of a dual transistor cell, or viewed alternatively, a memory cell with one-half word line per channel. Namely, the present technology has surprisingly found that by utilizing a unique doping and isolation arrangement, a single channel may be utilized to control two adjacent channels. For instance, the present technology provides for control of adjacent channels in a complimentary metal-oxide semiconductor, as well as other devices having arrangements such that adjacent channels carry opposite doping charges, utilizing a single word line. Thus, significant decreases in size per memory cell are achieved, which results in a DRAM array with increased memory density. Moreover, surprisingly, by utilizing such an arrangement, such decreases in size can be obtained even when the thickness of the shared word line is increased from conventional cells. Thus, the present technology provides for significant decreases in word line pitch for vertical cell DRAM arrays in addition to decreases in resistance due to the increased thickness of the shared word line. In addition, in embodiments, such a decrease in pitch may allow for corresponding decreases in capacitor size, decreasing the necessary drive current. In addition, the overall shrinkage in cell size may also allow for the inclusion of a substrate layer between the bit line and the channels, in exemplary embodiments, providing a pathway for hole movement between channels when the gate is off, reducing the floating body effect impact on a defective channel.

The remaining disclosure will routinely identify specific vertical cell dynamic random-access memory (DRAM) cells and arrays and processes utilized for forming vertical cell dynamic random access memory cells and arrays, such as a 4F² DRAM device. In addition, the remaining disclosure will routinely identify specific complementary metal-oxide semiconductors (CMOS), and components thereof. However, it will be readily understood that the systems and methods are equally applicable to other DRAM and field-effect devices, other devices that would benefit from higher density, other devices suffering from a floating body effect, and orientations thereof, as well as processes for forming such devices. Accordingly, the technology should not be considered to be so limited as for use with these specific devices or systems alone. The disclosure will discuss one possible semiconductor device that may include one or more components according to embodiments of the present technology before additional variations and adjustments to this apparatus according to embodiments of the present technology are described.

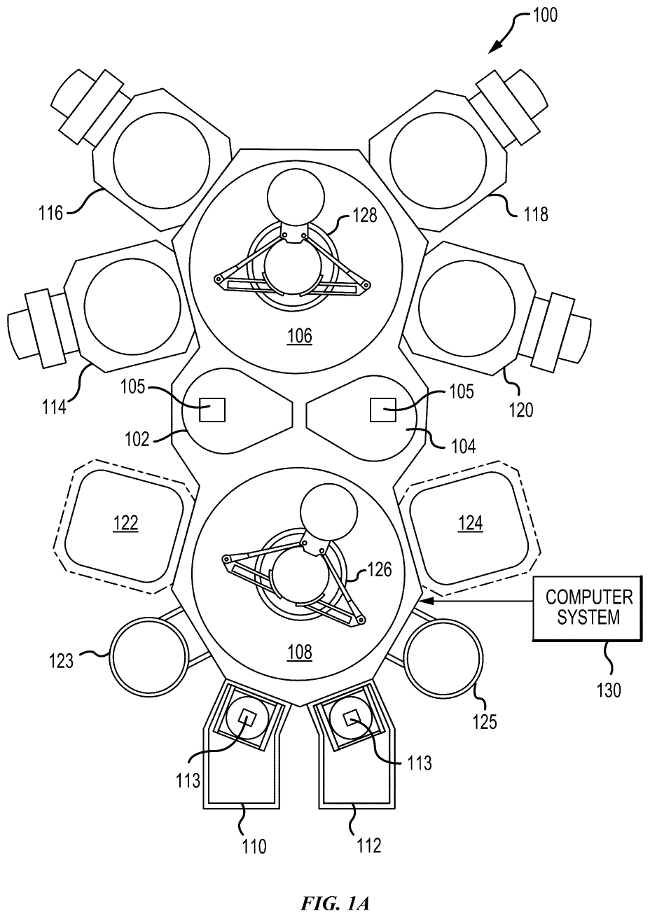

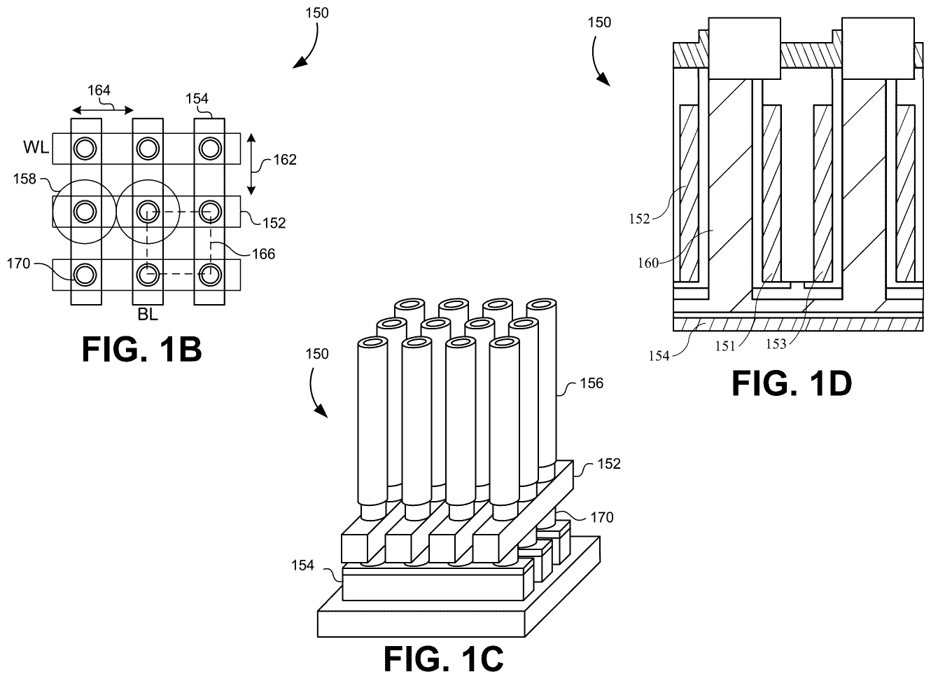

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108 and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general-purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B-1D illustrate top, perspective, and cross-sectional views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

As illustrated more clearly in FIG. 1D, and as discussed above, each channel 160 of a conventional 4F² memory array 150 contains two word lines 152 per channel 160 (e.g. conventional systems are typically double gated). Some conventional systems have been reduced to a single word line 152 per channel 160 by removing the word lines 151, 153 between adjacent channels, and replacing word lines 151 and 153 with an air gap. Air gaps, as known in the art, can be utilized to provide an effective oxide thickness between adjacent channels at an overall smaller width or thickness. However, as shown in FIG. 1D, each channel 160 would still contain at least one word line 152 per channel 160, as well as an air gap between adjacent channels, in order to isolate and turn on the respective channel.

Nonetheless, a plurality of vertical memory cells may be arranged over intersections between the plurality of word lines 152 and the plurality of bit lines 154. Each of the plurality of vertical memory cells may include a vertical transistor 170, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors 170 and capacitors in a rectangular orthogonal grid pattern (where generally orthogonal may be within about 10° from orthogonal, such as less than or about 7.5°, such as less than or about 5°, such as less than or about 2.5°, such as less than or about 1° from orthogonal, or any ranges or values therebetween) it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

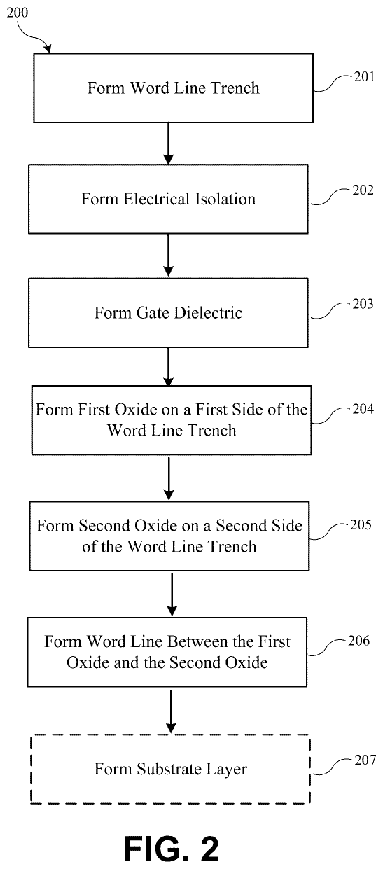

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

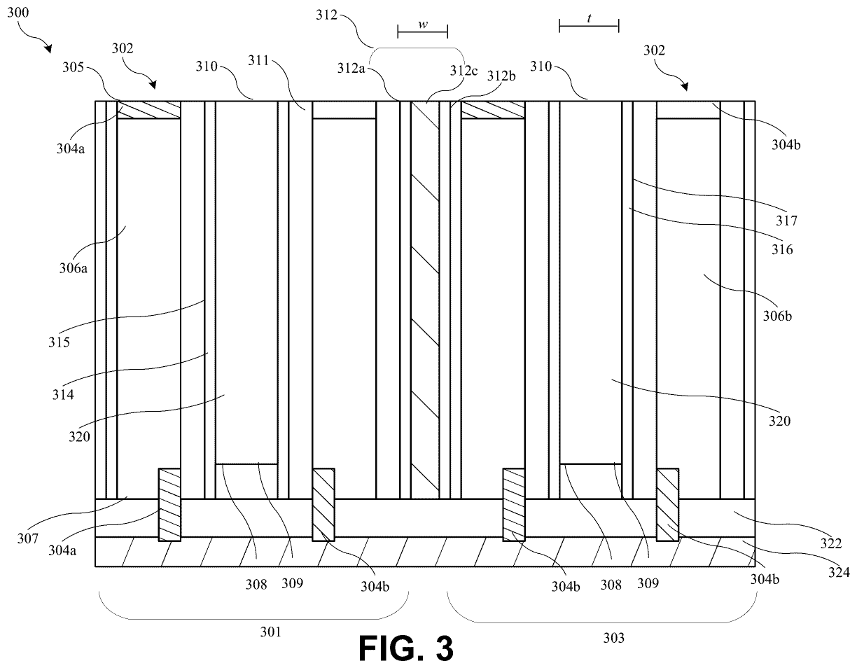

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations to develop the semiconductor structure 300 illustrated in FIG. 3, the illustration of which will be described in conjunction with the operations of method 200. It is to be understood that FIG. 3 illustrate only a partial schematic view, and a semiconductor substrate may include further components as illustrated in the figures, as well as alternative components, of any size or configuration that may still benefit from aspects of the present technology.

Method 200 may or may not involve optional operations to develop the semiconductor structure illustrated in FIG. 3 to a particular fabrication operation. It is to be understood that method 200 may be performed on any number of semiconductor structures 300, as illustrated in FIG. 3, including exemplary structures on which one or more layers or semiconductor features may be formed over a substrate. As illustrated in FIG. 3 the substrate material 302 (shown in polished and doped form after formation of the structure 300) may be any number of materials, such as a base wafer or substrate made of silicon or silicon-containing materials, germanium, other substrate materials, as well as one or more materials that may be formed overlying the substrate during semiconductor processing.

In embodiments, the structure 300 may be a semiconductor substrate, including bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 302 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

A semiconductor structure 300 according to embodiments of the present technology is illustrated in FIG. 3. As shown, in embodiments, a substrate material 302 has first source/drains 304a corresponding to a first channel 306a and second source/drains 304b corresponding to a second channel 306b. Each of the source/drain regions 304a and 304b are formed at a top surface 305 and an opposed lower surface 307 of the respective channel 306a, 306b. While the source/drains 304a, 304b formed adjacent to the lower surface 307 are shown as elongated tabs extending through only a portion of the thickness or width of the lower surface 307 of the respective channel 306a, 306b, which will be discussed in greater detail below, it should be understood that in embodiments, the source/drains 304a, 304b at the lower surface 307 may be formed identically to the source/drains 304a, 304b disposed at a top surface 305 of the respective channel 306a, 306b.

For instance, in embodiments, source/drains 304a, 304b may be formed by exposing the respective channel 306a, 306b to one or more ion implants followed by a subsequent anneal process. The implant process may be a single implant or may include a series of multiple implants. When multiple implants are utilized, each implant may utilize the same ion, or different ions. Although, it should be understood that the source/drains 304a, 304b may be formed from any suitable process. For instance, as known in the art, methods may include providing a semiconductor structure having first source/drain regions 304a, 304b for a plurality of vertical channels, and forming a plurality of word lines that contact the first source/drain regions. Overall, this process may incrementally form each stage of the transistor on top of a previous completed stage.

Moreover, while various deposition and fill processes may be utilized to deposit or fill any of the layers illustrated in FIG. 3 or otherwise discussed herein, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art to deposit any of the layers and materials discussed herein. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

Nonetheless, a method 200 for forming a semiconductor structure, such as semiconductor structure 300, can include, at operation 201, forming a word line trench 308, by etching, or other methods as known in the art. For instance, in embodiments, a substrate 302 may be loaded into load lock 110,112 and transferred to a process chamber (such as process chamber 114) via robots 126, 128, where the semiconductor structure 300 is subjected to a word line trench formation operation 201. It should be understood that the substrate may be transferred between each operation step, or only a portion of the operation steps, as some operation steps may be completed in the same processing chamber. Nonetheless, each word line trench 308 extends from a first end 309 to an opposed second end 310 and defines a trench depth therebetween. Moreover, word line trench formation operation 201 may be conducted by any method as known in the art.

In any event, while formation of the word line trench 308 may be occur by any method as known in the art, as discussed above, the present technology has surprisingly found that by carefully doping an oxide around an outer perimeter of a word line trench 308 and isolating adjacent channels not separated by a word line 320 (e.g., channels not sharing a word line 320 also referred to as channels in an adjacent cell), a single word line may be utilized to control two individual channels 306a, 306b located on opposite sides of word line 320. Thus, in embodiments, operation 201 may include only forming a single word line 320 for every two channels 306a, 306b, in semiconductor device 300. Thus, as illustrated, arrays according to the present technology may have a generally orientation of a first channel adjacent to a word line, a second channel adjacent to an opposite side of the world line from the first channel, and an electrical isolation adjacent to a second side of the second channel, spacing the second cell which may begin the orientation again, where each element is spaced apart along a first horizontal direction, which may be a first horizontal direction extending alone or parallel to bit line 324.

As illustrated in FIG. 3, in embodiments, an electrical isolation 312 may be formed between channels 306a, 306b in adjacent cells (e.g. channel 306b of first cell 301 and channel 306a of second cell 303 not separated by word line 320) at operation 202. Electrical isolation 312 may be formed simultaneously with word line formation operation 201 or may be formed or etched prior to or subsequent to the formation of word line trench 320.

In embodiments, electrical isolation 312 may contain any electrically isolating material known in the art, alone or in conjunction with an air gap. For instance, in embodiments, the electrically isolating material may be a dielectric material, such as a silicon oxide, silicon oxycarbide, silicon oxynitride, silicon oxycarbonitride, combinations thereof, or other dielectric material as known in the art, and/or an air gap, formed utilizing any fill methods discussed above and as known in the art. Although the following description will regularly discuss silicon oxide or silicon nitride as a dielectric material and/or a spacer material, it is to be understood that any number of dielectric materials may be used in embodiments of the present technology, and the present technology should not be limited to any particular dielectric material in which features may be formed.

In addition, while electrical isolation 312 is illustrated as containing two dielectric layers 312a and 312b in conjunction with an air gap 312c, it should be understood that electrical isolation 312 may be formed from one electrically insulating material, two electrically insulating materials, or more. For instance, in embodiments, air gap 312c may be eliminated, and electrical isolation 312 may be formed from one or more dielectric materials. Namely, in embodiments, dielectric material 312a and 312b may be formed from the same material, different materials, or materials that may have the same or different starting composition (e.g. a dielectric material doped to have different work functions, as will be discussed in greater detail). In addition, while more than one dielectric material or layer is illustrated, it should be clear that, in embodiments, only one dielectric material layer may be utilized in electrical isolation 312 depending on the isolation properties of the material selected. For instance, in embodiments, dielectric layers 312a and/or 312b may be eliminated, and an air gap 312c may be utilized alone, or with only one dielectric layer.

Notwithstanding the electrical isolation 312 formed, the electrical isolation 312 may have a width w that is less than or about 90% of a word line 320 thickness t, such as less than or about 85%, such as less than or about 80%, such as less than or about 75%, such as less than or about 70%, such as less than or about 65%, such as less than or about 60%, such as less than or about 55%, such as less than or about 50%, such as less than or about 45%, such as less than or about 40%, such as less than or about 35%, such as less than or about 30% of a word line 320 thickness t, or any ranges or values therebetween.

For instance, in embodiments, the electrically isolation 312 may have a width w of less than or about 12 nm, such as less than or about 11 nm, such as less than or about 10 nm, such as less than or about 9 nm, such as less than or about 8 nm, such as less than or about 7 nm, such as less than or about 6 nm, such as less than or about 5 nm, such as less than or about 4 nm, or any ranges or values therebetween.

Thus, due to the reduction in width of the electrical isolation 312, and as each channel only requires one-half of a word line according to the present technology, in embodiments, each of the formed word lines 320 may have an increased thickness t, without increasing the size of the cell. Thus, in embodiments, the thickness t may be greater than or about 5 nm, such as greater than or about 6 nm, such as greater than or about 7 nm, such as greater than or about 8 nm, such as greater than or about 9 nm, such as greater than or about 10 nm, such as greater than or about 11 nm, such as greater than or about 12 nm, such as greater than or about 13 nm, such as greater than or about 14 nm, such as greater than or about 15 nm, or any ranges or values therebetween.

Therefore, in embodiments, an increase in thickness t of word line 320 may be obtained even while decreasing the overall word line pitch by greater than or about 5%, such as greater than or about 7.5%, such as greater than or about 10%, such as greater than or about 12.5%, such as greater than or about 15%, such as greater than or about 17.5%, such as greater than or about 20%, such as greater than or about 22.5%, such as greater than or about 25%, as compared to a semiconductor structure have one word line per channel.

Stated differently, in embodiments, a semiconductor device 300 according to the present technology may exhibit a word line cell pitch of less than or about 45 nm, such as less than or about 42.5 nm, such as less than or about 40 nm, such as less than or about 37.5 nm, such as less than or about 35 nm, such as less than or about 32.5 nm, such as less than or about 30 nm, such as less than or about 27.5 nm, such as less than or about 25 nm, such as less than or about 22.5 nm, or any ranges or values therebetween.

Regardless of the thickness of the word line 320, width of the electrical isolation 312, or the ultimate cell size, the present technology has found that by carefully lining opposing sides of a gate dielectric 311 disposed around the outer perimeter of word line trench 308 with one or more dielectric materials having different work functions, a single word line 320 with the size advantages discussed herein, may be obtained that exhibits two different threshold voltages, and therefore does not sacrifice electrical properties. Thus, in embodiments, a gate dielectric 311 may be formed along channels 316a, 316b, at operation 203 utilizing methods as known in the art. In embodiments, the gate dielectric 311 may be formed from any one or more materials as discussed above, such as silicon oxide, in embodiments.

Nonetheless, after formation of gate dielectric 311 a first dielectric layer 314 is formed on a first side 315 of word line trench 308 at operation 204 and a second dielectric layer 316 is formed on an opposed second side 317 of word line trench 308 at operation 205, using any one or more of the methods discussed above and as known in the art. As will be discussed in greater detail, it should be understood that, in embodiments, the second dielectric layer 316 may be applied prior to the first dielectric layer 314.

In embodiments, the first dielectric layer 314, the second dielectric layer, or both the first dielectric layer 314 and the second dielectric layer 316 may be formed from any one or more of the dielectric materials discussed above. Nonetheless, in embodiments, the first dielectric layer 314, the second dielectric layer, or both the first dielectric layer 314 and the second dielectric layer 316 may be an oxide layer. In embodiments, the first dielectric layer 314, the second dielectric layer, or both the first dielectric layer 314 and the second dielectric layer 316 may be formed from, for example, silicon dioxide (SiO₂) and/or a high-k dielectric material. In embodiments, high-k dielectric materials can include any dielectric material having a dielectric constant of greater than or about 10, such as greater than or about 15, such as greater than or about 20, such as greater than or about 25, or any ranges or values therebetween, including aluminum oxide (Al₂O₃), hafnium oxide (HfO₂), hafnium oxynitride (HfON), hafnium silicate (HfSiO₄), zirconium oxide (ZrO₂), zirconium oxynitride (ZrON), zirconium silicate (ZrSiO₄), yttrium oxide (Y₂O₃), lanthanum oxide (La₂O₃), cerium oxide (CeO₂), titanium oxide (TiO₂), tantalum oxide (Ta₂O₅), other dielectric material or combinations thereof. The first dielectric layer 314, the second dielectric layer, or both the first dielectric layer 314 and the second dielectric layer 316 may be formed by, for example, a chemical vapor deposition (CVD) process, a physical vapor deposition (PVD) process, or other suitable semiconductor processes that are adapted to form a dielectric material layer as discussed above.

However, in embodiments, the high-k dielectric layer may be applied utilizing an atomic layer deposition (ALD) process, in which a metal-containing precursor and an oxygen-containing precursor are alternately delivered to the gate dielectric 311. In some embodiments, the metal-containing precursor is purged prior to delivering the oxygen-containing precursor. The metal may be a transition metal, such as hafnium (Hf), zirconium (Zr), or titanium (Ti), a rare-earth metal, such as lanthanum (La), ytterbium (Yb), or yttrium (Y), an alkaline earth metal, such as strontium (Sr), or other metal such as aluminum (Al). For the oxidant, any oxygen-containing precursor may be used that may react with the metal. For example, the oxygen-containing precursor may be or include water, diatomic oxygen, ozone, a hydroxyl-containing precursor or alcohol, nitrogen-and-oxygen-containing precursors, plasma-enhanced oxygen including locally or remotely enhanced oxygen, or any other material including oxygen that may be incorporated with the metal to produce a layer of an oxide of the metal over the gate dielectric 311.

Nonetheless, in embodiments, as discussed above, it should be understood that the first dielectric layer 314 and second dielectric layer 316 may be independently selected to have different work functions in order to impart different threshold differences to the word line adjacent to first dielectric layer 314 and second dielectric layer. 316. For instance, in embodiments, first side 315 of word line trench 308 may be adjacent to an n-MOS channel (e.g., channel 306a), and second side 317 of word line trench 308 may be adjacent to a p-MOS channel (e.g., channel 306b). In such an example, first dielectric 314 may be formed from materials that have a higher work function, and second dielectric 316 may be formed from materials that have a lower work function. In such a manner, the threshold voltage adjacent to a n-MOS channel (306a in this example) is higher than a threshold voltage adjacent to a p-most channel (306b in this example). Thus, in such a manner, both the n-MOS and p-MOS channel may be “off” when the gate is set to a near zero voltage. Moreover, when a positive voltage is applied to the gate, the n-MOS channel is activated while the p-MOS channel remains off, and when a negative voltage is applied to the gate, the n-MOS channel is activated while the p-MOS channel remains off. However, as should be clear to one having skill in the art, the orientation may be fully flipped, so long as the correct dielectric 314, 316 remains adjacent to the respective channel 306a, 306b (e.g. 306a may be a p-MOS channel and 314 may be a negative work function material, and 306b may be an n-MOS channel and 316 may be a higher work function material).

In embodiments, the first dielectric 314 may be adjacent to a n-MOS channel and may be formed from a material that creates a dipole between the first dielectric material 314 and the channel 306a, thus exhibiting a positive work function shift. In such an example, the first dielectric may include dielectrics and oxide materials containing aluminum (Al), niobium (Nb), Tantalum (Ta), or any metallic substance having Fermi level lower than that of hafnium (Hf). Suitable aluminum (Al)-containing materials include aluminum oxide (Al₂O₃) Suitable niobium (Nb)-containing materials include niobium nitride (NbN), niobium oxide (NbOx), and titanium niobium nitride (TiNbN).

Furthermore, in embodiments, the second dielectric 316 may be adjacent to a p-MOS channel and may be formed from a material that creates a dipole between the second dielectric material 316 and the channel 306b, but exhibiting a negative work function shift. In such an example, the first dielectric may include dielectrics and oxide materials containing one or more lanthanum (La) species, silicon nitrite, combinations thereof or one or more other species that would provide a negative work function shift as known in the art.

Namely, as discussed above, the present technology has surprisingly found that by utilizing such a first dielectric 314 and second dielectric 316, one or more threshold voltages as discussed herein can be obtained, even when utilizing very thin channels 306a, 306b. Thus, the dielectric materials discussed herein may help to provide a necessary threshold voltage between the word line 320 and an adjacent n-MOS channel as well as between the word line and an adjacent p-MOS channel.

It should be understood that in embodiments, the positive and negative work function materials are present during first dielectric 314 and second dielectric 316 layer formation. However, in some embodiments, an oxide layer may be formed first, followed by formation of a negative work function or positive work function material over the oxide layer. A subsequent anneal process may then be utilized to diffuse the positive work function or negative work function into the oxide layer, forming first dielectric 314 and/or second dielectric 316. In embodiments, such an anneal process may include a thermal anneal process in the presence of an inert gas. However, in embodiments, the underlying oxide may already contain the respective positive or negative work function material, (e.g., when utilizing one or more high-k dielectric materials discussed above), but then may also undergo additional incorporation of a work function material utilizing an anneal process in order to achieve the work function levels desired for activation and isolation of the respective channels.

For instance, the first dielectric 314, which may be adjacent to a n-MOS channel in this example, may have a positive work function so as to provide a region 315 between the word line or gate and the first dielectric 314 with a threshold voltage of greater than or about 0.5 volts (V), such as greater than or about 0.6 V, such as greater than or about 0.7 V, such as greater than or about 0.8 V, such as greater than or about 0.9 V, such as greater than or about 1 V, such as greater than or about 1.1 V, such as greater than or about 1.2 V, such as greater than or about 1.3 V, such as greater than or about 1.4 V, such as greater than or about 1.5 V, such as greater than or about 1.6 V, such as greater than or about 1.7 V, such as greater than or about 1.8 V, such as greater than or about 1.9 V, such as greater than or about 2 V, such as greater than or about 2.1 V, such as greater than or about 2.2 V, such as greater than or about 2.3 V, such as greater than or about 2.4 V, such as greater than or about 2.5 V, or any ranges or values therebetween.

Moreover, in embodiments, the second dielectric 316, which may be adjacent to a p-MOS channel in this example, may have a negative work function so as to provide a region 317 between the word line or gate and the second dielectric 316 with a threshold voltage of less than or about −0.5 volts (V), such as less than or about −0.6 V, such as less than or about −0.7 V, such as less than or about −0.8 V, such as less than or about −0.9 V, such as less than or about −1 V, such as less than or about −1.1 V, such as less than or about −1.2 V, such as less than or about −1.3 V, such as less than or about −1.4 V, such as less than or about −1.5 V, such as less than or about −1.6 V, such as less than or about −1.7 V, such as less than or about −1.8 V, such as less than or about −1.9 V, such as less than or about −2 V, such as less than or about −2.1 V, such as less than or about −2.2 V, such as less than or about −2.3 V, such as less than or about −2.4 V, such as less than or about −2.5 V, or any ranges or values therebetween.

Thus, in such embodiments, the word line or gate may be in the off position for both the n-MOS and p-MOS channels when having an applied voltage of greater than or about −0.4 V, such as greater than or about −0.3 V, such as greater than or about −0.2 V, such as greater than or about −0.1 V, such as less than or about 0.5 V, such as less than or about 0.4 V, such as less than or about 0.3 V, such as less than or about 0.2 V, such as less than or about 0.1 V, such as about 0 volts, or any ranges or values therebetween.

Moreover, a p-MOS channel may be turned on when the word line voltage is less than or about −2.6 V, such as less than or about −2.7 V, such as less than or about −2.8 V, such as less than or about −2.9 V, such as less than or about −3 V, such as less than or about −3.1 V, such as less than or about −3.2 V, such as less than or about −3.3 V, such as less than or about −3.4 V, such as less than or about −3.5 V, or any ranges or values therebetween.

Similarly, a n-MOS channel may be turned on when the word line voltage is greater than or about 2.6 V, such as greater than or about 2.7 V, such as greater than or about 2.8 V, such as greater than or about 2.9 V, such as greater than or about 3 V, such as greater than or about 3.1 V, such as greater than or about 3.2 V, such as greater than or about 3.3 V, such as greater than or about 3.4 V, such as greater than or about 3.5 V, or any ranges or values therebetween.

Moreover, due at least in part to the decreased capacitor sizes, the present technology has surprisingly found that lower drive current, even in a p-MOS region, is sufficient to drain charge off of the respective capacitor. Thus, the present technology provides for smaller memory cells which provide improved memory cell density, while maintaining excellent electrical properties between the capacitors and transistors, as well as across the cell and array.

Nonetheless, after formation of the first dielectric layer 314 and second dielectric layer 316, the word line 320 may be formed at operation 206 utilizing any method as known in the art. The word line may extend in a second horizontal direction different than the first horizontal direction. In embodiments, the word line may be a low-resistance metal, such as tungsten, titanium nitride, titanium, ruthenium, cobalt, molybdenum, the like, or combinations thereof. As illustrated, in embodiments, the word line 320 may be etched back below a second source/drain region 304a/304b adjacent to a first end 309 of the word line trench 308.

In embodiments, an optional substrate layer 322 may be formed over a surface of the cell 301 adjacent to the lower surface 307 of channels 306a, 306b at optional operation 207. Namely, as discussed above, due to the decreased size enabled by the present technology, it may be desirable to include an additional substrate layer 322 while still obtaining an overall decrease in cell size. In embodiments, if a substrate layer 322 is included, it may be desirable to include alternating vertical layers (e.g. a direction generally orthogonal to the first and second horizontal directions, such as the vertical direction of vertically extending channels 320) of p-type substrate below n-MOS regions and n-type substrate below p-MOS regions. In such a manner the present technology may provide for the reduction or elimination of the floating body effect exhibited by 4F² arrays, as the doped substrate regions can act as p-wells and n-wells connected to the bit line 324, attracting minority carriers from defective channels.

Thus, in embodiments, the substrate layer 322 may be formed by sidewall epitaxy. In such an embodiment, moving horizontally along the first horizontal direction (e.g. along bit line 324) from left to right across FIG. 3, a layer of p-type substrate may be deposited starting at sidewall 326 and moving towards source/drain 304a. At source/drain 304a, a vertical layer of a material having a different etch specificity from the substrate layer 322 may be deposited, such as SiGe when doped Si is utilized as the substrate, as an example only. A further deposition of a substrate material, which may be p-doped or n-doped is then deposited utilizing sidewall epitaxy, until second source/drain 304b is reached, at which point another vertical layer of the selective etch material may be deposited, followed by deposition of an n-type substrate below a p-MOS region. After such a substrate formation operation 207, the selective etch material may be removed, and source/drain regions 304a, 304b may be formed in the etched area. However, as discussed above, it should be understood that, in embodiments, no substrate layer 322 may be utilized, and source drain regions 304a, 304b may be formed according to standard processes, such as ion implantation discussed above.

Regardless of whether a substrate layer 322 is formed, a bit line 324 is formed in contact with lower surface 307 source/drains 304a/304b, extending in the first horizontal direction. Bit lines 324 may be formed from a material deposited by any suitable technique known in the art, such as one or more deposition or filing techniques discussed above. In some embodiments, the bit line(s) 324 includes one or more of tungsten (W), ruthenium (Ru), iridium (Ir), platinum (Pt), rhodium (Rh) or molybdenum (Mo). In embodiments, the bit line 324 material is one or more of ruthenium or tungsten.

After formation of the bit line 324, the semiconductor structure 300 may re-enter a normal process flow for a vertical cell DRAM array, such as a 4F² DRAM array, and undergo one or more further processing steps. For instance, the semiconductor structure 300 may undergo contact formation and redistribution, bonding pad formation, and/or copper contact formation. Nonetheless, semiconductor structure may exhibit a drastically smaller size and increased density, alone or in combination with reduced or even eliminated floating body effect.

Nonetheless, in embodiments, it may be necessary to utilize contact pads spaced connecting a capacitor to the transistor. Such as, in embodiments where the electrical isolation 312 has a width w smaller than a word line 320 thickness t, as such a reduction in thickness results in lack of uniformity in spacing across the cells, which may also be referred to as a mismatched overlay. In such embodiments, the cell contact may be staggered a portion of a pitch from center for each row (e.g., one row a portion of a pitch stagger to the right, the following row a portion of a pitch stagger to the left), providing good contacts for each row. However, in embodiments, no stagger may be necessary based upon the width of the word line and the thickness of the electrical isolation 312.

It should be appreciated that the specific steps illustrated in the figures provide particular methods of forming 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMS, EEPROMs, magnetic or optical cards, flash memory, or other types of machine-readable mediums suitable for storing electronic instructions. Alternatively, the methods may be performed by a combination of hardware and software.

What is claimed is:

1. A vertical dynamic random-access memory (DRAM) cell, comprising:
a bit line arranged in a first horizontal direction;
a first channel;
a second channel; and
a shared word line arranged in a second horizontal direction between the first channel and the second channel;
wherein the first channel and the second channel extend in a vertical direction that is generally orthogonal to the first horizontal direction and the second horizontal direction such that the bit line intersects with a source/drain region of the first channel and the second channel, and the shared word line intersects with a gate region of both the first channel and second channel.

2. The vertical dynamic random-access memory (DRAM) cell of claim 1, wherein the vertical dynamic random-access memory (DRAM) cell contains only one word line for every two channels.

3. The vertical dynamic random access memory (DRAM) cell of claim 1, further comprising a first dielectric layer extending from a first end a word line trench to a second end of the word line trench along a first side, wherein the second end is opposite the first end, and a second dielectric layer extending from the first end of the word line trench to the second end of the word line trench along a second side, wherein the second side is opposite the first side.

4. The vertical dynamic random-access memory (DRAM) cell of claim 3, further comprising wherein the first dielectric layer is formed from a material having a first work function, and wherein the second dielectric layer is formed from a material having a second work function, wherein the first work function is different than the second work function.

5. The vertical dynamic random-access memory (DRAM) cell of claim 4, wherein the first side is adjacent to the first channel and the second side is adjacent to the second channel, wherein the first channel comprises a n-MOS channel and the second channel comprises a p-MOS channel.

6. The vertical dynamic random-access memory (DRAM) cell of claim 5, wherein the first dielectric layer material comprises a positive work function material.

7. The vertical dynamic random-access memory (DRAM) cell of claim 6, wherein the first dielectric layer material comprises an oxide containing aluminum (Al), niobium (Nb), Tantalum (Ta), a metallic substance having Fermi level lower than that of hafnium (Hf), or combinations thereof.

8. The vertical dynamic random-access memory (DRAM) cell of claim 5, wherein the second dielectric layer material comprises a negative work function material.

9. The vertical dynamic random-access memory (DRAM) cell of claim 8, wherein the second dielectric layer material comprises an oxide containing one or more lanthanum species, silicon nitrite, or combinations thereof.

10. A vertical cell dynamic random-access memory (DRAM) array, comprising:
a first vertical dynamic random access memory cell disposed adjacent to a second vertical dynamic random access memory cell, wherein the first vertical dynamic random access memory cell and the second dynamic random access memory cell comprise:
a bit line arranged in a first horizontal direction,
a first channel,
a second channel, and
a word line arranged in a second horizontal direction between the first channel and the second channel,
wherein the first channel and the second channel extend in a vertical direction that is generally orthogonal to the first horizontal direction and the second horizontal direction such that the bit line intersects with a source/drain region of the first channel and the second channel, and the word line intersects with a gate region of the first channel and second channel; and
an electrical isolation between the first vertical dynamic random access memory cell and the second vertical dynamic random access memory cell.

11. The vertical cell dynamic random-access memory (DRAM) array of claim 10, wherein the first vertical dynamic random access memory cell and the second vertical dynamic random access memory cell each comprise only one word line for every two channels.

12. The vertical cell dynamic random-access memory (DRAM) array according to claim 10, further comprising a third vertical dynamic random access memory cell adjacent to the second vertical dynamic random access memory cell, wherein an electrical isolation is disposed between the second vertical dynamic random access memory cell and the third vertical dynamic random access memory cell, and wherein the third vertical dynamic random access memory cell comprises a shared word line between two adjacent channels.

13. The vertical cell dynamic random-access memory (DRAM) array according to claim 10, wherein electrical isolation comprises one or more dielectric materials, an air gap, or a combination thereof.

14. The vertical cell dynamic random-access memory (DRAM) array according to claim 10, further comprising a substrate layer disposed between the bit line and the source/drain region of the first channel and the second channel.

15. A method of forming a vertical dynamic random-access memory (DRAM) cell, comprising:
etching a word line trench between a first vertically extending channel and a second vertically extending channel, the word line trench having a first end opposite a second end and a first side opposite a second side;
forming a shared word line in the word line trench such that the word line intersects with a gate region of both the first vertically extending channel and second vertically extending channel.

16. The method of claim 15, further comprising lining the word line trench with a gate dielectric prior to forming the shared word line.

17. The method of claim 16, further comprising forming a first dielectric material over the gate dielectric along the first side of the word line trench; and forming a second dielectric material over the gate dielectric along the second side of the word line trench.

18. The method of claim 17, comprising forming a substrate layer by sidewall epitaxy over the vertical dynamic random access memory cell adjacent to the second end of the word line trench and a bit line layer over the substrate layer.

19. The method of claim 18, wherein the substrate layer is formed from alternating layers of a p-type substrate material, a selective etch material, and a n-type substrate material.

20. The method of claim 19, further comprising removing the selective etch material, and forming source/drain connections between the first vertically extending channel and the bit line and the second vertically extending channel and the bit line.
